(19) United States
(12) Patent Application Publication
(10) Pub. No.: US 2024/0119323 A1
(43) Pub. Date: Apr. 11, 2024

(54) METHOD AND DEVICE FOR RISK PREDICTION OF THERMAL RUNAWAY IN LITHIUM-ION BATTERIES

(71) Applicant: Beijing Institute of Technology, Beijing (CN)

(72) Inventors: Huixing MENG, Beijing (CN); Qiaoqiao YANG, Beijing (CN); Zhiming YIN, Beijing (CN); Cheng WANG, Beijing (CN); Te HAN, Beijing (CN); Jinduo XING, Beijing (CN)

(73) Assignee: Beijing Institute of Technology, Beijing (CN)

(21) Appl. No.: 18/318,846

(22) Filed: May 17, 2023

(30) Foreign Application Priority Data
Oct. 9, 2022 (CN) 202211225274.1

(51) Int. Cl. G06N 7/01; G06N 20/10

(52) U.S. Cl. CPC G06N 7/01; G06N 20/10

(57) ABSTRACT

One or more embodiments of the present description provide a method and device for risk prediction of thermal runaway in LIB. The method includes: acquiring knowledge of a mechanism for thermal runaway in LIB; describing an evolution process of thermal runaway in LIB by adopting a fault tree; mapping a fault tree structure to a dynamic Bayesian network model for thermal runaway in LIB to obtain quantitative results of a risk of thermal runaway in LIB; and taking the quantitative results of a dynamic Bayesian network as inputs of a machine learning model to obtain prediction results of the risk of thermal runaway. By using the method in the present embodiment, an evolution trend of battery thermal runaway can be predicted by fusing multiple thermal runaway causes and multi-source data, and thus, the prediction results are relatively accurate.

### CROSS-REFERENCE TO RELATED APPLICATIONS

The application claims priority to Chinese patent application No. 202211225274.1, filed on Oct. 9, 2022, the entire contents of which are incorporated herein by reference.

### TECHNICAL FIELD

One or more embodiments of the present description relate to the technical field of batteries, in particular to a method and device for risk prediction of thermal runaway in lithium-ion batteries (LIB).

### BACKGROUND

LIB have been widely applied to the field of new energy power batteries due to the advantages such as high energy density, high energy efficiency, long cycle life, and low self-discharge rate. With the increase of service time, there is a risk that thermal runaway accidents occur. The prediction for a battery thermal runaway risk can clarify a development mechanism of thermal runaway and quantify a risk of a battery state, thereby sending out early warning signals in advance to prevent and control thermal runaway events. However, in current prediction methods, one or more battery performance feature parameters are often extracted for prediction, and there are few studies from the perspective of system safety. Therefore, how to accurately predict an evolution trend of a battery thermal runaway risk from the perspective of system safety is a problem to be solved.

### SUMMARY

To this end, objectives of one or more embodiments of the present description are to provide a method and device for risk prediction of thermal runaway in LIB, by which a trend of a risk of thermal runaway in LIB can be predicted.

Based on the above-mentioned objectives, one or more embodiments of the present description provide a method for risk prediction of thermal runaway in LIB, including:
acquiring knowledge of a mechanism for thermal runaway in LIB;
describing an evolution process of thermal runaway in LIB by adopting a fault tree; mapping a fault tree structure to a dynamic Bayesian network model for thermal runaway in LIB to obtain quantitative results of a risk of thermal runaway in LIB; and
taking the quantitative results of a dynamic Bayesian network as inputs of a machine learning model to obtain prediction results of the risk of thermal runaway in LIB.

Optionally, the describing an evolution process of thermal runaway in LIB by adopting a fault tree includes:
utilizing the fault tree to analyze a triggering process of an accident for thermal runaway in LIB from two aspects of human and material factors by taking thermal runaway in LIB as a top event to obtain a fault tree model, wherein the human factor refers to emergency response failure for early abnormal heating-up, and the material factor refers to abnormal heating-up caused by mechanical abuse, electrical abuse, thermal abuse, etc.

Optionally, the mapping a fault tree structure to a dynamic Bayesian network model for thermal runaway in LIB to obtain quantitative results of a risk of thermal runaway in LIB includes:
mapping the fault tree structure to the dynamic Bayesian network, which includes graphic and numerical conversion: during graphic conversion, a top event, an intermediate event and a basic event of the fault tree are respectively mapped as a leaf node, an intermediate node and a root node of the Bayesian network, and the nodes are connected in the same way as the corresponding events; and during numerical conversion, an occurrence probability of the basic event is taken as a prior probability of the corresponding root node, and a conditional probability table is adopted to represent a relationship between the nodes; and
optionally, acquiring the prior probability and dependency between nodes within normal life of a battery in the dynamic Bayesian network from various channels such as statistical data, an open data set, and expert knowledge, and outputting Bayesian-inference-based quantitative results of the risk of thermal runaway in LIB.

Optionally, taking the quantitative results of a dynamic Bayesian network as inputs of a machine learning model to obtain prediction results of the risk of thermal runaway includes:
dividing the quantitative results of the risk of thermal runaway of the dynamic Bayesian network into a training set and a test set, and taking the training set and the test set as inputs of the support vector regression model supporting parameter grid search to obtain the prediction results of the risk of thermal runaway.

An embodiment of the present description further provides an apparatus for risk prediction of thermal runaway in LIB, including:
an acquisition module configured to acquire knowledge of a mechanism for thermal runaway in LIB;
a structurized module configured to decompose a triggering process of thermal runaway in LIB to obtain a structurized model;
a quantification module configured to calculate a risk of thermal runaway in LIB; and
a prediction module configured to take results from the quantification module as inputs of a machine learning model to obtain prediction results of the risk of thermal runaway in LIB.

Optionally, the structurized module is configured to utilize a fault tree to decompose a triggering process of thermal runaway in LIB and analyze a triggering process of an accident for thermal runaway in LIB from two aspects of human and material factors by taking thermal runaway in LIB as a top event to obtain a structurized fault tree model including 10 basic events and 6 intermediate events.

Optionally, the quantification module is configured to map a fault tree structure to a dynamic Bayesian network, which includes graphic and numerical conversion: during graphic conversion, a top event, an intermediate event and a basic event of the fault tree are respectively mapped as a leaf node, an intermediate node and a root node of the Bayesian network, and the nodes are connected in the same way as the corresponding events; and during numerical conversion, an occurrence probability of the basic event is taken as a prior probability of the corresponding root node, and a conditional probability table is adopted to represent a relationship between the nodes; and
optionally, acquiring the prior probability and dependency between nodes within normal life of a battery in the dynamic Bayesian network from various channels such as statistical data, an open data set, and expert knowledge, and outputting quantitative results of the risk of thermal runaway in LIB by using GeNie software.

Optionally, the prediction module is configured to divide the quantitative results of the risk of thermal runaway in LIB of the dynamic Bayesian network into a training set and a test set, and inputting the training set and the test set into a support vector regression model including parameter grid search to obtain the prediction results of the risk of thermal runaway in LIB.

It can be seen from above that, according to the method and device for risk prediction of thermal runaway in LIB in one or more embodiments of the present description, thermal runaway in LIB used as a main cause of electric vehicle fire and explosion is decomposed by utilizing the fault tree to obtain a structurized thermal runaway accident evolution model, the thermal runaway fault tree is mapped to the dynamic Bayesian network to obtain the quantitative results of the risk of thermal runaway within the normal life, the support vector regression model is selected after the training set and the test set are divided, and thus, the risk of thermal runaway in LIB can be predicted. By using the method in the present embodiment, the trend of battery thermal runaway is predicted in conjunction with a triggering mechanism of thermal runaway in LIB by considering influences of battery life on a thermal runaway probability, and thus, the prediction results are more accurate.

### BRIEF DESCRIPTION OF DRAWINGS

To describe the technical solutions in one or more embodiments of the present description or the prior art more clearly, the accompanying drawings required for describing the embodiments or the prior art will be briefly introduced below. Apparently, the accompanying drawings in the following description show only one or more embodiments of the present description, and those of ordinary skill in the art may still derive other accompanying drawings from these accompanying drawings without creative efforts.

FIG. 1 is a schematic process diagram of the proposed method in one or more embodiments of the present description;

FIG. 2 is a schematic diagram of a fault tree model in one or more embodiments of the present description;

FIG. 3 is a schematic diagram of a dynamic Bayesian network model in one or more embodiments of the present description; and

FIG. 4 is a structural block diagram of an apparatus in one or more embodiments of the present description.

### DETAILED DESCRIPTION OF THE EMBODIMENTS

In order to make the objectives, technical solutions and advantages of the present disclosure clearer and more understandable, the present disclosure will be further described in detail below in conjunction with specific embodiments and with reference to the accompanying drawings.

It should be noted that, unless otherwise defined, technical terms or scientific terms used in one or more embodiments of the present description shall be ordinary meanings as understood by those of ordinary skill in the art to which the present disclosure belongs. The words “first”, “second” and similar terms used in the one or more embodiments of the present description do not denote any order, quantity or importance, but are merely used to distinguish different components. The word “including” or “includes” and the like means that the element or object preceding the word covers the element or object listed after the word and its equivalent, without excluding other elements or objects. The words “connection” or “connected” and the like are not limited to physical or mechanical connections, but may include electrical connections, whether direct or indirect. The words “upper”, “lower”, “left”, “right” and the like are merely used to denote a relative positional relationship, and after an absolute position of the described object is changed, the relative positional relationship may also be correspondingly changed.

In the related art, research on a thermal runaway mechanism of lithium batteries is only explained on a macroscopic theoretical level, or stays in a laboratory stage. There is a big difference between added external interference and a real condition. The prediction for thermal runaway is mostly to extract individual or several parameters as features, which is not comprehensive enough, thereby resulting in inability to make a risk prevention decision for a system-safety lithium-ion battery thermal runaway.

To this end, the present application provides a method for risk prediction of lithium-ion battery thermal runaway in conjunction with various causes of battery thermal runaway, which is more in line with an actual situation of a battery, more accurate in prediction results and higher in actual application value.

Hereinafter, the technical solutions of the present application will be further described in detail with a specific embodiment.

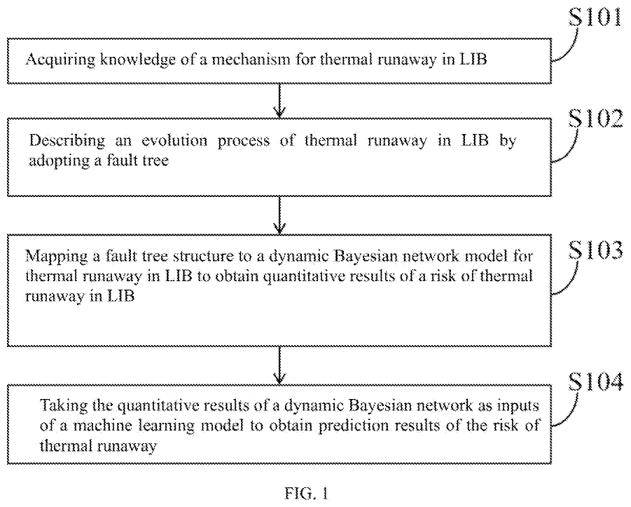

As shown in FIG. 1, the present application provides a method for risk prediction of thermal runaway in LIB, including:

S101: knowledge of a mechanism for thermal runaway in LIB is acquired;
in the present embodiment, firstly, the mechanism for thermal runaway in LIB is generalized and induced. In some implementations, a working state signal of a battery may be collected in real time, and a cause of thermal runaway is inferred according to the variation of the working state signal. The working state signal may be a surface temperature, a voltage and other parameters of the battery.

S102: an evolution process of thermal runaway in LIB is described by adopting a fault tree;
in the present embodiment, thermal runaway in LIB is directly caused by concurrence of a material factor (i.e., abnormal heating-up), and a human factor (i.e., emergency response failure). The abnormal heating-up is caused by situations of mechanical abuse, thermal abuse, electrical abuse, etc. A thermal runaway accident will be caused in a case of emergency response failure for early abnormal heating-up.

S103: a fault tree structure is mapped to a dynamic Bayesian network model for thermal runaway in LIB to obtain quantitative results of a risk of thermal runaway in LIB;
in some implementations, the fault tree structure may be mapped to a dynamic Bayesian network, a dependency and prior probability of each node of a battery in the dynamic Bayesian network may be acquired according to multi-source information such as statistical data, an open data set, and expert knowledge, and Bayesian-inference-based quantitative results of the risk of thermal runaway in LIB are outputted by virtue of Bayesian software such as GeNie.

S104: the quantitative results of a dynamic Bayesian network are taken as inputs of a machine learning model to obtain prediction results of the risk of thermal runaway;
in the present embodiment, the quantitative results of the risk of thermal runaway of the dynamic Bayesian network are divided into a training set and a test set, and the training set and the test set are taken as inputs of the support vector regression model supporting parameter grid search to obtain the prediction results of the risk of thermal runaway in LIB.

The method for risk prediction of thermal runaway in LIB in the present embodiment includes: knowledge of a mechanism for thermal runaway in LIB is acquired; an evolution process of thermal runaway in LIB is described by adopting a fault tree; a fault tree structure is mapped to a dynamic Bayesian network model for thermal runaway in LIB to obtain quantitative results of a risk of thermal runaway in LIB; and the quantitative results of a dynamic Bayesian network are taken as inputs of a machine learning model to obtain prediction results of the risk of thermal runaway. By using the method in the present embodiment, a trend of battery thermal runaway is predicted by integrating multi-aspect thermal runaway causes and acquiring data from multiple channels, and thus, the prediction results are relatively accurate, which is beneficial to prevention and control of thermal runaway in LIB accidents.

The method in the present application will be described in detail below in conjunction with the accompanying drawings and specific embodiments.

Based on the collected knowledge of the mechanism for thermal runaway in LIB, the fault tree is built with thermal runaway as a top event, which includes the specific steps that:
firstly, direct, necessary and sufficient causes of the top event are determined from top event analysis. These causes are used as intermediate events to further determine their direct, necessary and sufficient causes, and upper and lower layers are connected by a logic gate, and thus, an inverted tree diagram is formed by gradual unfolding from top to bottom.

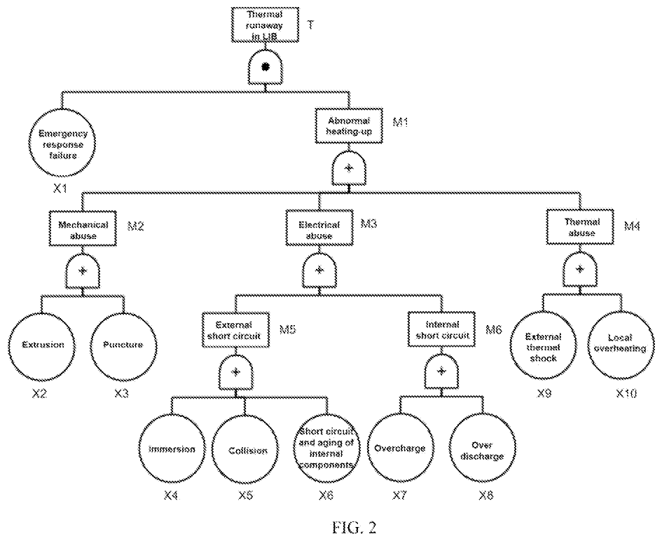

In the present example, the fault tree of thermal runaway in LIB is shown in FIG. 2, 10 basic events refer to Table 1, and a thermal runaway accident will be caused in a case of emergency response failure for early abnormal heating-up. Situations under which abnormal heating-up occurs specifically include:
the mechanical abuse is divided into extrusion and puncture according to different situations of variation caused after the battery is mechanically abused.

The electrical abuse usually includes internal short circuit and external short circuit; when the battery is in a state of overcharge or overdischarge, it is easy to cause internal short circuit; and external short circuit is caused by immersion and collision of the battery or short circuit and aging of internal components of a battery pack.

The thermal abuse may be divided into two situations of local overheating of the battery and external thermal shock from surrounding objects.

TABLE 1
Basic Event of Fault Tree of Thermal Runaway

| Serial number | Name of basic events |
|---|---|
| X1 | Emergency response failure |
| X2 | Extrusion |
| X3 | Puncture |
| X4 | Immersion |
| X5 | Collision |
| X6 | Short circuit and aging of |
| | internal components |
| X7 | Overcharge |
| X8 | Overdischarge |
| X9 | External thermal shock |
| X10 | Local overheating |

The fault tree is mapped to the dynamic Bayesian network, which includes graphic and numerical conversion. During graphic conversion, a top event, an intermediate event and a basic event of the fault tree are respectively mapped as a leaf node, an intermediate node and a root node of the Bayesian network, and the nodes are connected in the same way as the corresponding events; and during numerical conversion, an occurrence probability of the basic event is taken as a prior probability of the corresponding root node, and a conditional probability table is adopted to represent a relationship between the nodes. In some examples, the dependency between parts of the nodes is expressed by 0 and 1 to express the logical “AND” and logical “OR” in the fault tree.

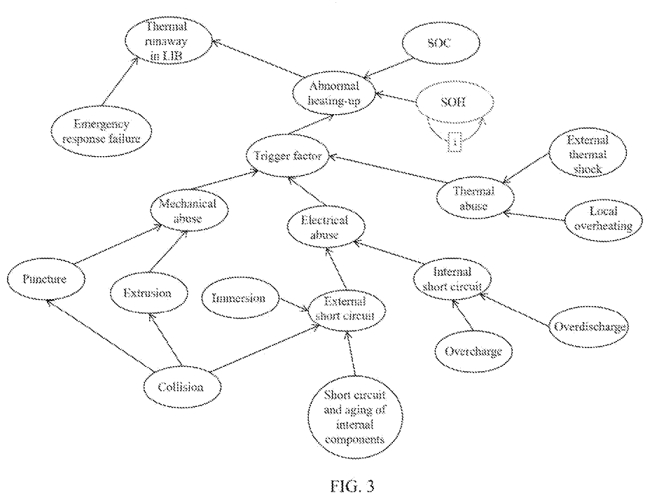

In the present example, the mapped dynamic Bayesian network is shown in FIG. 3.

Optionally, two nodes (i.e., SOC and SOI) having crucial impact on abnormal heating-up are added to the network. SOC refers to state of charge, studies have shown that electrolyte is prone to decompose on a cathode interface under high SOC, with a larger instantaneous current when the external short circuit occurs. A higher SOC means faster heat release rates and more energy release under external heating. SOH refers to the state of health of a battery, which is also referred to as a state of life. An aged LIB (i.e., an LIB with a lower SOH) may enter thermal runaway earlier than new ones and the initial temperature of thermal runaway decreases over cycles, especially when SOH is less than 80%.

In some examples, all the statistical data, open data set and expert knowledge may be used as data sources of the prior probability of the dynamic Bayesian network. The expert knowledge is acquired by questionnaire. In the present example, a failure probability is calculated by adopting a fuzzy set theory, and thus, the problem that it is difficult to precisely express with less historical data is partially solved.

In the present example, the dynamic Bayesian network model runs by using GeNie software to obtain time series of the risk of thermal runaway. The time series are inputted into a support vector regression model to predict a trend of thermal runaway.

The basic premise of support vector regression is projecting nonlinear data in reality into a high-dimensional feature space, so that the problem is turned into a linear regression problem.

Assuming that a linear function in the high-dimensional feature space is expressed as:

f(x)=ω·ϕ(x)+b
where parameters ω and b are calculated targets, and ϕ(x) is a nonlinear mapping function.

By adopting a grid search method, parameters such as linear insensitive loss in the support vector regression model may be obtained, and then, a Lagrange equation and a kernel function are introduced to obtain values of the calculated targets. Optionally, a mapping problem is solved by adopting radial basis functions.

The training set and the test set are divided according to ratios 9:1, 8:2 and 7:3 of the time series and are inputted into the support vector regression model to obtain the prediction results of the risk of thermal runaway. Optionally, the coefficient of determination (R²) is adopted to indicate and predict a fitting performance and is expressed as:

$${R}^{2} = 1 - \frac{{\sum }_{i = 1}^{n} {( {y}_{i} - \hat{y} )}^{2}}{{\sum }_{i = 1}^{n} {( {y}_{i} - \overline{y} )}^{2}}$$

where yᵢ represents real observed values, ŷ represents predicted values, and y̅ represents an average value of the real observed values.

Advantages of the method in the present embodiment will be described below in conjunction with experimental data.

In the present embodiment, the dynamic Bayesian network model for quantifying the risk of thermal runaway is built according to a prismatic lithium battery charge-discharge cycle data set, statistical data and expert knowledge from CALCE Battery Research Group at University of Maryland. A data set is divided according to ratios 9:1, 8:2 and 7:3 with the time series of the thermal runaway probability generated by the dynamic Bayesian network as inputs based on a support vector regression method. The obtained fitting performance is good, and the value of R² reaches 99.98% or above.

TABLE 2
Prediction Results of Battery Risk of Thermal Runaway

| Method | R² |
|---|---|
| Quadratic regression | 0.8781 |
| Recurrent neural network | 0.9646 |
| Long short-term memory network | 0.9994 |
| Gated recurrent unit | 0.9784 |
| Support vector regression | 0.9999 |

According to an experimental result from Table 2, compared with a quadratic regression model, a recurrent neural network, a long short-term memory network, and a gated recurrent unit model, the support vector regression model in the present description is higher in value of R², which proves that its prediction effect is better. For thermal runaway in LIB, the present example proposes the method in which the fault tree, the dynamic Bayesian network and support vector regression prediction are combined, which can form a set of accident mechanism model including various causes and achieve relative accurate risk prediction, and has certain effectiveness.

It should be noted that a specific embodiment of the present description has been described as above. Other embodiments fall within the scope of the appended claims. In some cases, actions or steps recorded in the claims may be performed in an order different from that in the embodiment and may be still used to achieve a desired result. In addition, the process described in the accompanying drawing does not necessarily require the shown specific or sequential order to achieve the desired result. In some implementations, multi-task processing and concurrent processing are also feasible or may be favorable.

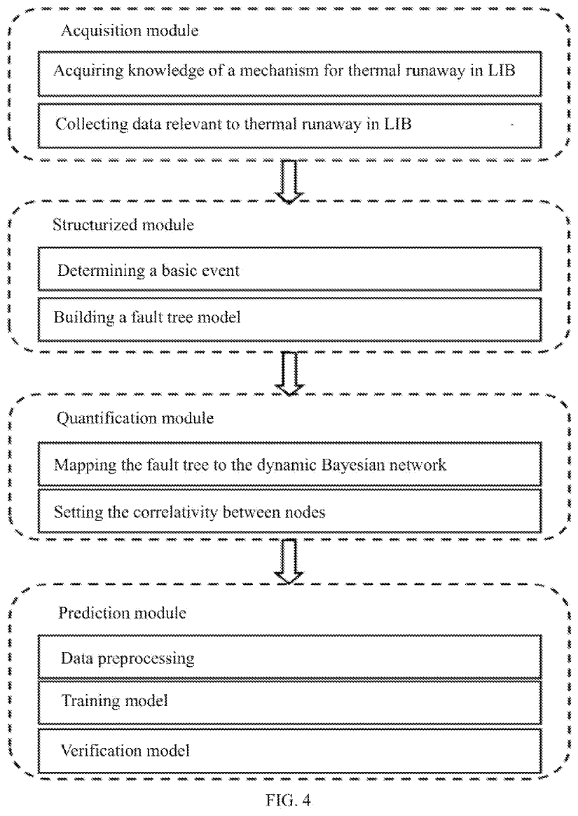

As shown in FIG. 4, an embodiment of the present description further provides an apparatus for risk prediction of thermal runaway in LIB, including:
an acquisition module configured to acquire knowledge of a mechanism for thermal runaway in LIB;
a structurized module configured to decompose a triggering process of thermal runaway in LIB to obtain a structurized model;
a quantification module configured to calculate a risk of thermal runaway in LIB; and
a prediction module configured to take results from the quantification module as inputs of a machine learning model to obtain prediction results of the risk of thermal runaway.

For facilitating description, the above-mentioned apparatus is divided into the various modules to be respectively described according to functions during description. Of course, functions of the various modules may be implemented in the same or more software and/or hardware when one or more embodiments of the present description are implemented.

The apparatus in the above-mentioned embodiment is used to implement the corresponding method in the foregoing embodiment and has the beneficial effects of the corresponding method embodiment, the descriptions thereof are not to be repeated herein.

The present disclosure has been described in conjunction with the specific embodiments of the present disclosure, however, a number of replacements, modifications and variations of these embodiments will be apparent to those of ordinary skill in the art according to the foregoing description.

The one or more embodiments of the present description aim at covering all such replacements, modifications and variations falling within the broad scope of the appended claims. Therefore, any omissions, modifications, equivalent replacements, improvements and the like made without departing from the spirit and principle of the one or more embodiments of the present description shall fall within the protection scope of the present disclosure.

What is claimed is:

1. A method for risk prediction of thermal runaway in LIB, comprising: acquiring knowledge of a mechanism for thermal runaway in LIB; describing an evolution process of thermal runaway in LIB by adopting a fault tree; mapping a fault tree structure to a dynamic Bayesian network model for thermal runaway in LIB to obtain quantitative results of a risk of thermal runaway in LIB; and taking the quantitative results of a dynamic Bayesian network as inputs of a machine learning model to obtain prediction results of the risk of thermal runaway in LIB;
the fault tree being configured to systemically induce the knowledge of the mechanism for thermal runaway and graphically represent evolution of thermal runaway in LIB by virtue of events and a logic relationship therebetween;
the mapping being configured to convert the fault tree structure and parameters into the corresponding dynamic Bayesian network to represent a more complex node relationship, and perform risk quantification by using a Bayesian algorithm; and
the machine learning model referring to a support vector regression model configured to predict a trend of the risk of thermal runaway.

2. The method of claim 1, wherein the describing an evolution process of thermal runaway in LIB by adopting a fault tree comprises:
utilizing the fault tree to analyze a triggering process of an accident for thermal runaway in LIB from two aspects of human and material factors by taking thermal runaway in LIB as a top event to obtain a fault tree model, wherein the human factor refers to emergency response failure for early abnormal heating-up, and the material factor refers to abnormal heating-up caused by mechanical abuse, electrical abuse, thermal abuse, etc.

3. The method of claim 1, wherein the mapping a fault tree structure to a dynamic Bayesian network model for thermal runaway in LIB to obtain quantitative results of a risk of thermal runaway comprises:
mapping the fault tree structure to the dynamic Bayesian network, which comprises graphic and numerical conversion: during graphic conversion, a top event, an intermediate event and a basic event of the fault tree are respectively mapped as a leaf node, an intermediate node and a root node of the Bayesian network, and the nodes are connected in the same way as the corresponding events; and during numerical conversion, an occurrence probability of the basic event is taken as a prior probability of the corresponding root node, and a conditional probability table is adopted to represent a relationship between the nodes; and acquiring the prior probability and dependency between nodes of the dynamic Bayesian network according to multi-source information such as statistical data, an open data set, and expert knowledge to obtain Bayesian-inference-based quantitative results of the risk of thermal runaway in LIB.

4. The method of claim 1, wherein the taking the quantitative results of a dynamic Bayesian network as inputs of a machine learning model to obtain prediction results of the risk of thermal runaway comprises:
dividing the quantitative results of the risk of thermal runaway of the dynamic Bayesian network into a training set and a test set, and taking the training set and the test set as inputs of the support vector regression model supporting parameter grid search to obtain the prediction results of the risk of thermal runaway.

5. An apparatus for risk prediction of thermal runaway in LIB, comprising:
an acquisition module configured to acquire knowledge of a mechanism for LIB thermal runaway;
a structurized module configured to decompose a triggering process of thermal runaway in LIB to obtain a structurized model;
a quantification module configured to calculate a risk of thermal runaway in LIB; and
a prediction module configured to take results from the quantification module as inputs of a machine learning model to obtain prediction results of the risk of thermal runaway.

6. The method of claim 5, wherein
the structurized module is configured to utilize a fault tree to decompose a triggering process of thermal runaway in LIB and analyze a triggering process of an accident for thermal runaway in LIB from two aspects of human and material factors by taking thermal runaway in LIB as a top event to obtain a fault tree model.

7. The method of claim 5, wherein
the quantification module is configured to map a fault tree structure to a dynamic Bayesian network, which comprises graphic and numerical conversion: during graphic conversion, a top event, an intermediate event and a basic event of the fault tree are respectively mapped as a leaf node, an intermediate node and a root node of the Bayesian network, and the nodes are connected in the same way as the corresponding events; and during numerical conversion, an occurrence probability of the basic event is taken as a prior probability of the corresponding root node, and a conditional probability table is adopted to represent a relationship between the nodes; and acquiring the prior probability and dependency between nodes within normal life of a battery in the dynamic Bayesian network from various channels such as statistical data, an open data set, and expert knowledge, and outputting quantitative results of the risk of thermal runaway in LIB.

8. The method of claim 5, wherein
the prediction module is configured to divide the quantitative results of the risk of thermal runaway of the dynamic Bayesian network into a training set and a test set, and inputting the training set and the test set into a support vector regression model including parameter grid search to obtain the prediction results of the risk of thermal runaway.
